(19) United States
(12) Patent Application Publication
(10) Pub. No.: US 2013/0270576 A1
(43) Pub. Date: Oct. 17, 2013

(54) SILICON CARBIDE SEMICONDUCTOR DEVICE

(71) Applicant: SUMITOMO ELECTRIC INDUSTRIES, LTD., Osaka-shi (JP)

(72) Inventors: Takeyoshi Masuda, Osaka-shi (JP); Keiji Wada, Osaka-shi (JP); Toru Hiyoshi, Osaka-shi (JP)

(73) Assignee: Sumitomo Electric Industries, Ltd., Osaka-shi (JP)

(21) Appl. No.: 13/785,801

(22) Filed: Mar. 5, 2013

Related U.S. Application Data
(60) Provisional application No. 61/623,291, filed on Apr. 12, 2012.

(30) Foreign Application Priority Data
Apr. 12, 2012 (JP) 2012-090727

(51) Int. Cl. H01L 29/04

(52) U.S. Cl. CPC H01L 29/045
USPC 257/77

(57) ABSTRACT

A silicon carbide semiconductor device has a planar layout configured by periodically arranging unit cells. The unit cells include valid cells and invalid cells. Each of the valid cells has a switchable channel surface. The invalid cells are to relax electric field in the valid cells. At least one of the valid cells is disposed between adjacent ones of the invalid cells.

### BACKGROUND OF THE INVENTION

1. Field of the Invention

The present invention relates to a silicon carbide semiconductor device.

2. Description of the Background Art

Structures have been examined to further improve breakdown voltage of a silicon carbide semiconductor device such as a MOSFET (Metal Oxide Semiconductor Field Effect Transistor). Japanese Patent Laying-Open No. 2008-270681 discloses a MOSFET having a breakdown voltage structure portion surrounding the circumference of an active region. Japanese Patent Laying-Open No. 2009-194065 discloses a MOSFET having a trench reaching an n⁻ drift layer. This trench has a side surface provided with a p type deep layer.

According to Japanese Patent Laying-Open No. 2008-270681, the breakdown voltage structure portion provides electric field relaxation only in the outer circumferential portion of the active region. This is likely to result in insufficient improvement of breakdown voltage. According to Japanese Patent Laying-Open No. 2009-194065, each trench is provided with the p type deep layer for electric field relaxation. This results in significant current confinement.

### SUMMARY OF THE INVENTION

The present invention has been made to solve the foregoing problem and has its object to provide a silicon carbide semiconductor device so as to suppress current confinement while increasing breakdown voltage.

A silicon carbide semiconductor device according to one aspect of the present invention has a planar layout configured by periodically arranging unit cells. The silicon carbide semiconductor device includes a plurality of valid cells and a plurality of invalid cells. The plurality of valid cells are included in the plurality of unit cells. Each of the plurality of valid cells has a switchable channel surface. The plurality of invalid cells are included in the plurality of unit cells. The plurality of invalid cells are for relaxing electric field in the plurality of valid cells. At least one of the plurality of valid cells is disposed between adjacent ones of the plurality of invalid cells.

In the silicon carbide semiconductor device according to the above-described one aspect, at least one of the plurality of valid cells is disposed between the adjacent ones of the plurality of invalid cells. Accordingly, significant current confinement, which would have taken place when the invalid cells are disposed directly adjacent to each other, can be avoided.

Preferably in the silicon carbide semiconductor device according to the above-described one aspect, the plurality of invalid cells are periodically arranged in the plurality of unit cells.

Accordingly, electric field relaxation provided by the invalid cells can affect the valid cells more uniformly. Accordingly, breakdown voltage can be more improved.

Preferably in the silicon carbide semiconductor device according to the above-described one aspect, each of the plurality of valid cells has a source electrode.

Accordingly, carriers can be provided from the source electrode to each of the valid cells.

A silicon carbide semiconductor device according to another aspect of the present invention has a planar layout configured by periodically arranging unit cells. The silicon carbide semiconductor device has a plurality of valid cells and an invalid region. The plurality of valid cells are included in the plurality of unit cells. The plurality of valid cells are periodically arranged to provide a plurality of lattice points. Each of the plurality of valid cells has a switchable channel surface. The plurality of lattice points include a plurality of normal lattice points and a plurality of relaxation lattice points. At least one of the plurality of normal lattice points is disposed between adjacent ones of the plurality of relaxation lattice points. The invalid region is for relaxing electric field in the plurality of valid cells. The invalid region is disposed for each of the plurality of relaxation lattice points.

In the silicon carbide semiconductor device according to the above-described another aspect, at least one of the plurality of normal lattice points is disposed between the adjacent ones of the plurality of relaxation lattice points. Accordingly, significant current confinement, which would have taken place when the relaxation lattice points are disposed directly adjacent to each other, can be avoided.

Preferably in the silicon carbide semiconductor device according to the above-described another aspect, the plurality of relaxation lattice points are periodically disposed in the plurality of lattice points.

Accordingly, electric field relaxation provided by the relaxation lattice points can affect the valid cells more uniformly. Accordingly, breakdown voltage can be more improved.

A silicon carbide semiconductor device according to still another aspect of the present invention has a planar layout configured by periodically arranging unit cells. The silicon carbide semiconductor device has a plurality of valid cells and an invalid region. The plurality of valid cells are included in the plurality of unit cells, and are periodically arranged. Each of the plurality of valid cells has a switchable channel surface. Each of the plurality of valid cells has an outer edge surrounded by a plurality of sides. The plurality of valid cells are in contact with each other with the plurality of sides serving as a plurality of boundaries. The plurality of boundaries have a plurality of normal boundaries and a plurality of relaxation boundaries. At least one of the plurality of normal boundaries is disposed between adjacent ones of the plurality of relaxation boundaries. The invalid region is for relaxing electric field in the plurality of valid cells. The invalid region is disposed for each of the plurality of relaxation boundaries.

Accordingly, at least one of the plurality of normal boundaries is disposed between the adjacent ones of the plurality of relaxation boundaries. Accordingly, significant current confinement, which would have taken place when the relaxation boundaries are disposed directly adjacent to each other, can be avoided.

Preferably in the silicon carbide semiconductor device according to the above-described still another aspect, the plurality of relaxation boundaries are periodically arranged in the plurality of boundaries.

Accordingly, electric field relaxation provided by the relaxation boundaries can affect the valid cells more uniformly. Accordingly, breakdown voltage can be more improved.

The silicon carbide semiconductor device according to each of the above-described aspects is preferably of trench gate type.

Accordingly, the area of the unit cell can be made smaller. This leads to downsizing of the silicon carbide semiconductor device.

Preferably, the silicon carbide semiconductor device according to each of the above-described aspects includes a substrate, a gate insulating film, and a gate electrode. The substrate is made of silicon carbide having a hexagonal crystal structure of polytype 4H. The substrate is provided with a surface including a first plane having a plane orientation of {0-33-8}. The surface includes the channel surface. The gate insulating film is provided on the surface of the substrate. The gate electrode is provided on the gate insulating film.

Accordingly, the channel surface includes the first plane having a plane orientation of {0-33-8}. Accordingly, the channel resistance is restrained, thereby achieving restrained on-resistance.

Further, preferably, the surface microscopically includes the first plane. Moreover, the surface microscopically includes a second plane having a plane orientation of {0-11-1}.

Accordingly, the channel resistance can be further restrained. Thus, the on-resistance can be further restrained.

More preferably, the first and second planes of the substrate form a combined plane having a plane orientation of {0-11-2}.

Accordingly, the channel resistance can be further restrained. Thus, the on-resistance can be further restrained.

Further, preferably, the surface of the substrate macroscopically has an off angle of 62°±10° relative to a {000-1} plane.

Accordingly, the channel resistance can be further restrained. Thus, the on-resistance can be further restrained.

As described above, according to the present invention, the current confinement can be suppressed while increasing the breakdown voltage.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial plan view schematically showing a planar layout of a silicon carbide semiconductor device in a first embodiment of the present invention.

FIG. 2 is a schematic partial cross sectional view taken along a line II-II in FIG. 1, and schematically shows a configuration of the silicon carbide semiconductor device in the first embodiment of the present invention.

FIG. 3 is a perspective view schematically showing a shape of a silicon carbide substrate of FIG. 2.

FIG. 4 shows that surfaces of p type are provided with hatching in the perspective view of FIG. 3.

FIG. 5 is a partial cross sectional view schematically showing a first step in a method for manufacturing a silicon carbide semiconductor device in FIG. 2.

FIG. 6 is a partial cross sectional view schematically showing a second step in the method for manufacturing the silicon carbide semiconductor device in FIG. 2.

FIG. 7 is a partial cross sectional view schematically showing a third step in the method for manufacturing the silicon carbide semiconductor device in FIG. 2.

FIG. 8 is a partial cross sectional view schematically showing a fourth step in the method for manufacturing the silicon carbide semiconductor device in FIG. 2.

FIG. 9 is a partial cross sectional view schematically showing a fifth step in the method for manufacturing the silicon carbide semiconductor device in FIG. 2.

FIG. 10 is a partial cross sectional view schematically showing a sixth step in the method for manufacturing the silicon carbide semiconductor device in FIG. 2.

FIG. 11 is a partial cross sectional view schematically showing a seventh step in the method for manufacturing the silicon carbide semiconductor device in FIG. 2.

FIG. 12 is a partial cross sectional view schematically showing an eighth step in the method for manufacturing the silicon carbide semiconductor device in FIG. 2.

FIG. 13 is a partial cross sectional view schematically showing a ninth step in the method for manufacturing the silicon carbide semiconductor device in FIG. 2.

FIG. 14 is a partial cross sectional view schematically showing a tenth step in the method for manufacturing the silicon carbide semiconductor device in FIG. 2.

FIG. 15 is a partial cross sectional view schematically showing an eleventh step in the method for manufacturing the silicon carbide semiconductor device in FIG. 2.

FIG. 16 is a partial cross sectional view schematically showing a twelfth step in the method for manufacturing the silicon carbide semiconductor device in FIG. 2.

FIG. 17 shows a variation of FIG. 1.

FIG. 18 shows a variation of FIG. 1.

FIG. 19 shows a variation of FIG. 1.

FIG. 20 shows a variation of FIG. 1.

FIG. 21 shows a variation of FIG. 1.

FIG. 22 shows a variation of FIG. 1.

FIG. 23 shows a variation of FIG. 1.

FIG. 24 is a partial cross sectional view schematically showing a configuration of a silicon carbide semiconductor device in a second embodiment of the present invention.

FIG. 25 is a partial cross sectional view schematically showing a first step in a method for manufacturing the silicon carbide semiconductor device in FIG. 24.

FIG. 26 is a partial cross sectional view schematically showing a second step in the method for manufacturing the silicon carbide semiconductor device in FIG. 24.

FIG. 27 is a partial cross sectional view schematically showing a third step in the method for manufacturing the silicon carbide semiconductor device in FIG. 24.

FIG. 28 is a partial plan view schematically showing a planar layout of a silicon carbide semiconductor device in a third embodiment of the present invention.

FIG. 29 is a schematic partial cross sectional view taken along a line XXIX-XXIX in FIG. 28, and schematically shows a configuration of the silicon carbide semiconductor device in the third embodiment of the present invention.

FIG. 30 shows a variation of FIG. 28.

FIG. 31 shows a variation of FIG. 28.

FIG. 32 shows a variation of FIG. 28.

FIG. 33 is a partial plan view schematically showing a planar layout of a silicon carbide semiconductor device in a fourth embodiment of the present invention.

FIG. 34 shows a variation of FIG. 33.

FIG. 35 shows a variation of FIG. 33.

FIG. 36 shows a variation of FIG. 33.

FIG. 37 is a partial cross sectional view schematically showing a fine structure of the substrate provided in the silicon carbide semiconductor device.

FIG. 38 shows a crystal structure of the (000-1) plane in the hexagonal crystal of polytype 4H.

FIG. 39 shows a crystal structure of the (11-20) plane along a line XXXIX-XXXIX in FIG. 38.

FIG. 40 shows a crystal structure in the (11-20) plane in the vicinity of the surface of the combined plane in FIG. 37.

FIG. 41 shows the combined plane of FIG. 37 when viewed from the (01-10) plane.

FIG. 42 is a graph chart showing one exemplary relation between channel mobility and an angle between the channel surface and the (000-1) plane when viewed macroscopically, in each of a case where thermal etching is performed and a case where no thermal etching is performed.

FIG. 43 is a graph chart showing one exemplary relation between channel mobility and an angle between the channel direction and the <0-11-2> direction.

FIG. 44 shows a variation of FIG. 37.

### DESCRIPTION OF THE PREFERRED EMBODIMENTS

The following describes embodiments of the present invention based on figures. It should be noted that in the below-mentioned figures, the same or corresponding portions are given the same reference characters and are not described repeatedly. Regarding crystallographic indications in the present specification, an individual orientation is represented by [ ], a group orientation is represented by < >, an individual plane is represented by ( ) and a group plane is represented by { }. In addition, a negative crystallographic index is normally indicated by putting “-” (bar) above a numeral, but is indicated by putting the negative sign before the numeral in the present specification.

### First Embodiment

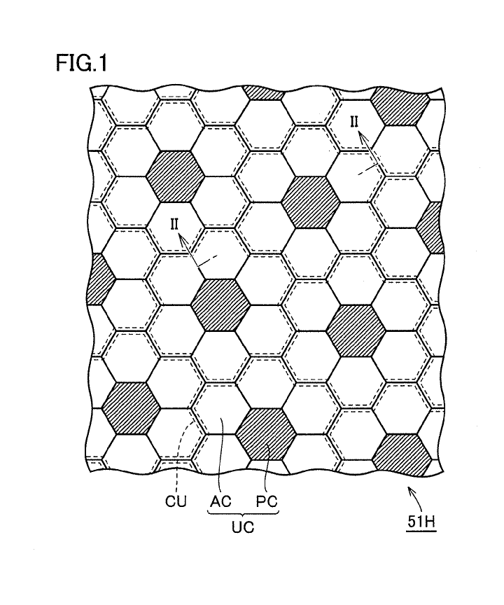

Referring to FIG. 1, gist of the present embodiment will be described first.

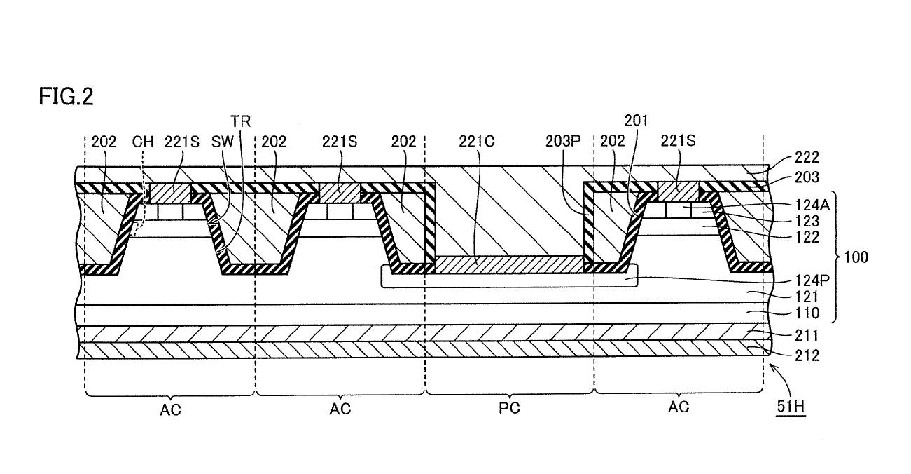

A MOSFET (silicon carbide semiconductor device) 51H of the present embodiment has a planar layout configured by periodically arranging unit cells UC. Each of unit cells UC has a shape of polygon having sides and vertices. In the present embodiment, each of unit cells UC has a shape of hexagon, preferably, has a shape of regular hexagon. Unit cells UC include valid cells AC and invalid cells PC. Each of valid cells AC has a switchable channel surface CH (FIG. 2) as described below. Each of invalid cells PC is provided to relax electric field in valid cells AC. Invalid cell PC is a cell in which substantially no principal current flows, i.e., a cell in which current path is invalidated, unlike valid cell AC. Invalid cell PC has no channel surface CH, thereby invalidating the current path, for example. At least one valid cell AC is disposed between adjacent invalid cells PC.

Preferably, invalid cells PC are periodically disposed in unit cells UC. In the configuration of FIG. 1, they are arranged such that three-fold symmetry of the planar layout is maintained.

Further, in the present embodiment, valid cells AC and invalid cells PC form cell groups CU. Each of cell groups CU includes an invalid cell PC and valid cells AC surrounding it. Accordingly, invalid cell PC in one cell group CU is separated from invalid cell PC in its adjacent cell group CU by two or more valid cells AC.

Referring to FIG. 2 to FIG. 4, the following describes a configuration of MOSFET 51H in detail.

As shown in FIG. 2, specifically, MOSFET 51H is a vertical type VMOSFET (V-groove MOSFET). MOSFET 51 H includes an epitaxial substrate 100, gate insulating films 201, gate electrodes 202, interlayer insulating films 203, source electrodes 221S, a relaxing electrode 221C, a drain electrode 211, a source wiring member 222, and a protecting electrode 212.

Epitaxial substrate 100 is made of silicon carbide. Preferably, epitaxial substrate 100 has a hexagonal polytype of 4H. Preferably, a single-crystal substrate 110 has one main surface (upper surface in FIG. 2) having a plane orientation corresponding to approximately the (000-1) plane.

Specifically, epitaxial substrate 100 has single-crystal substrate 110 and an epitaxial layer provided thereon. The epitaxial layer includes an n⁻ layer 121 (breakdown voltage holding layer), p type body layers 122, n regions 123, contact regions 124A, and a relaxing region 124P. Single-crystal substrate 110, n⁻ layer 121, and n regions 123 have n type conductivity (first conductivity type), whereas p type body layers 122, contact regions 124A, and relaxing region 124P have p type conductivity (second conductivity type).

N⁻ layer 121 has an impurity concentration lower than that of single-crystal substrate 110. Each of p type body layers 122 is formed on n⁻ layer 121. N regions 123 are formed on portions of p type body layer 122 so as to be separated from n⁻ layer 121 by p type body layer 122. Each of contact regions 124A is formed on a portion of p type body layer 122 so as to be connected to p type body layer 122.

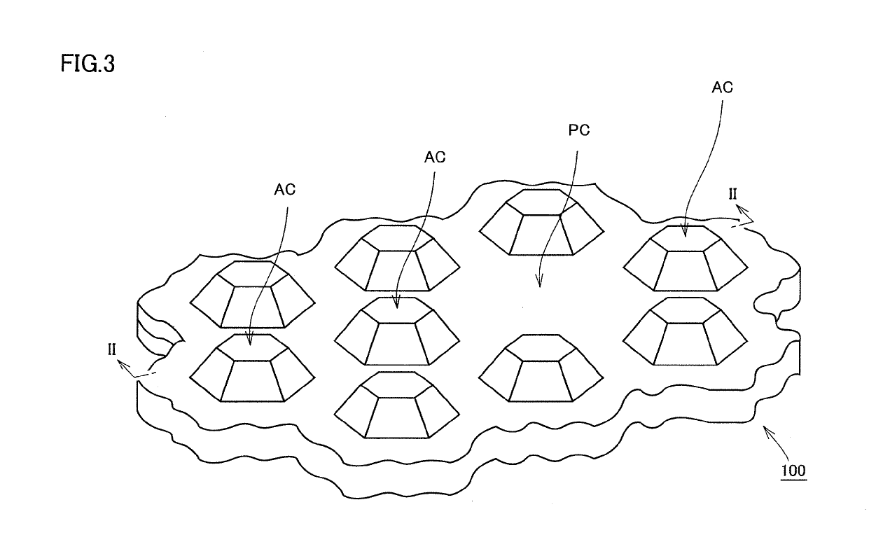

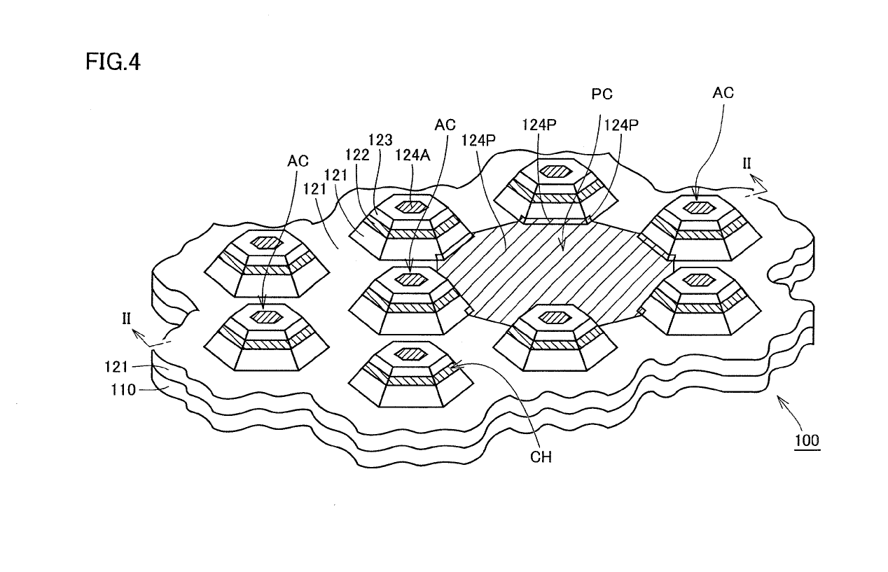

The epitaxial layer on the upper surface of single-crystal substrate 110 is partially removed to form a plurality of (three in FIG. 2) mesa structures. Specifically, each of the mesa structures has upper surface and bottom surface both having a hexagonal shape, and has side walls inclined relative to the upper surface of single-crystal substrate 110 as shown in FIG. 3. Further, epitaxial substrate 100 has surfaces of n type (surfaces provided with no hatching in FIG. 4) and surfaces of p type (surfaces provided with hatching in FIG. 4).

The mesa structures are provided only in locations corresponding to valid cells AC among valid cells AC and invalid cells PC. Further, epitaxial substrate 100 includes relaxing region 124P (FIG. 2 and FIG. 4), which is provided at a location corresponding to invalid cell PC, for relaxing electric field.

Between the mesa structures of valid cells AC directly adjacent to each other, a trench TR (FIG. 2) is formed to have a bottom surface and surfaces SW constituted of the side walls of the mesa structures. Each of surface SW has a channel surface CH on p type body layer 122. Surface SW has a predetermined crystal plane (also referred to as “special plane”). Details of the special plane will be described later.

Gate insulating film 201 is formed on surfaces SW and bottom surface of trench TR. Gate insulating film 201 extends onto the upper surface of each of n regions 123. Gate insulating film 201 has an opening in invalid cell PC so as to expose relaxing region 124P. In this opening, relaxing electrode 221C serving as an ohmic electrode is provided on relaxing region 124P.

On gate insulating film 201, gate electrode 202 is provided to fill trench TR (i.e., fill the space between the mesa structures directly adjacent to each other). Gate electrode 202 has an upper surface substantially as high as the upper surface of a portion of gate insulating film 201 on the upper surface of n region 123. Interlayer insulating film 203 is provided to cover gate electrode 202 as well as the portion of gate insulating film 201 on the upper surface of n region 123. Further, interlayer insulating film 203 includes a portion 203P that separates source wiring member 222 on relaxing electrode 221 C and gate electrode 202 from each other.

Each of source electrodes 221S is provided at the apex portion of each mesa structure provided in each valid cell AC. Source electrode 221S is in contact with each of contact region 124A and n region 123.

Source wiring member 222 is in contact with each of source electrode 221S and relaxing electrode 221C, and extends on the upper surface of interlayer insulating film 203.

Drain electrode 211 is an ohmic electrode provided on the backside surface of single-crystal substrate 110 opposite to its main surface on which n⁻ layer 121 is provided. Protecting electrode 212 is provided on drain electrode 211.

The following describes a method for manufacturing MOSFET 51H.

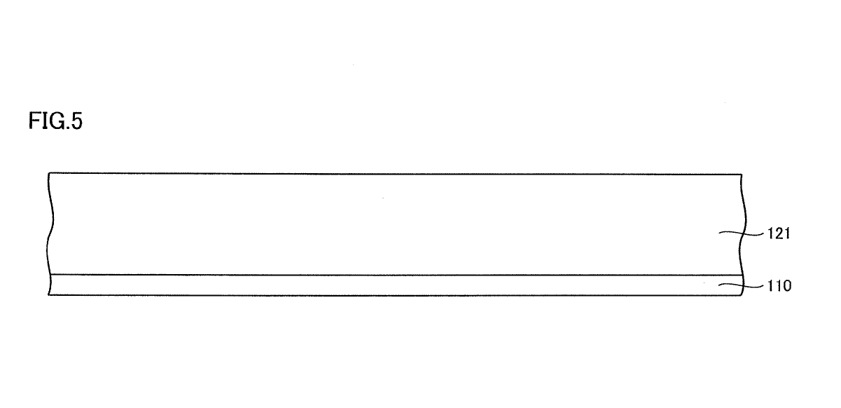

As shown in FIG. 5, on single-crystal substrate 110, n⁻ layer 121 is formed by means of epitaxial growth. This epitaxial growth can be achieved by employing a CVD (Chemical Vapor Deposition) method that utilizes a mixed gas of silane (SiH₄) and propane (C₃H₈) as a material gas and utilizes hydrogen gas (H₂) as a carrier gas, for example. In doing so, it is preferable to introduce nitrogen (N) or phosphorus (P) as an impurity of n type conductivity, for example. N⁻ layer 121 has an impurity concentration of, for example, not less than 5×10¹⁵/cm³ and not more than 5×10¹⁶/cm³.

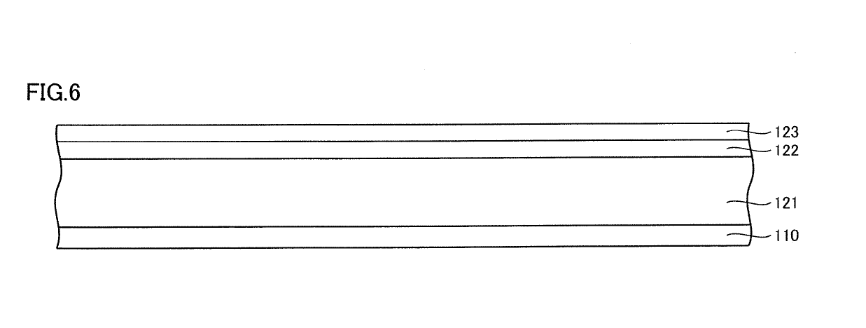

As shown in FIG. 6, ions are implanted into the upper surface of n⁻ layer 121, thereby forming p type body layer 122 and n region 123. In the ion implantation for forming p type body layer 122, ions of an impurity for providing p type such as aluminum (Al) are implanted. Meanwhile, in the ion implantation for forming n region 123, ions of an impurity for providing n type such as phosphorus (P) are implanted, for example. It should be noted that instead of the ion implantation, epitaxial growth may be performed.

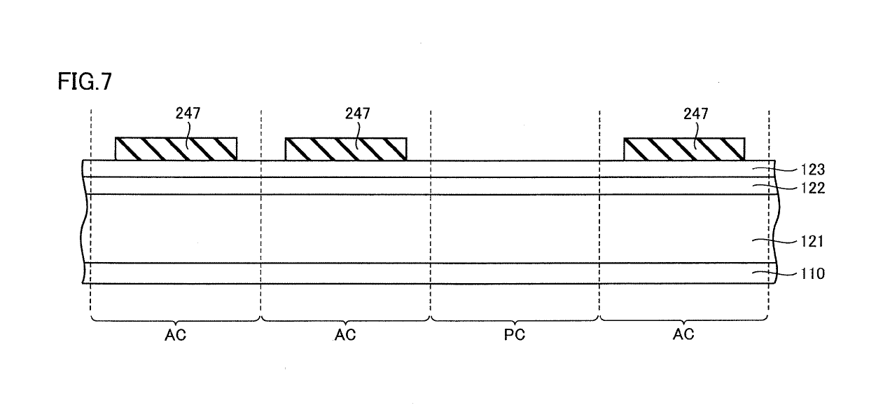

As shown in FIG. 7, mask layers 247 having an opening are formed on the upper surface of n region 123. As mask layers 247, insulating films such as silicon oxide films can be used. The opening is formed at locations in conformity with the locations of trench TR (FIG. 2) and invalid cell PC.

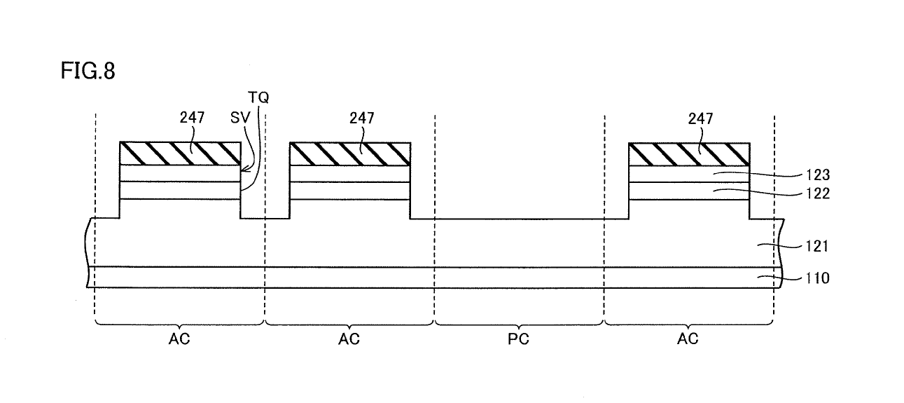

As shown in FIG. 8, in the opening of mask layers 247, n region 123, p type body layer 122, and portions of n⁻ layer 121 are removed by etching. An exemplary, usable etching method is reactive ion etching (RIE), in particular, inductively coupled plasma (ICP) RIE. Specifically, for example, ICP-RIE can be used which employs SF₆ or a mixed gas of SF₆ and O₂ as the reactive gas. By means of such etching, in the region where trench TR (FIG. 2) is to be formed, a recess TQ can be formed which has a side wall having a surface SV substantially perpendicular to the main surface of single-crystal substrate 110.

Next, side wall SV of recess TQ of the epitaxial substrate is thermally etched. This thermal etching to the substrate can be performed by, for example, heating the substrate in an atmosphere containing reactive gas having at least one or more types of halogen atom. The at least one or more types of halogen atom include at least one of chlorine (Cl) atom and fluorine (F) atom. This atmosphere is, for example, Cl₂, BCL₃, SF₆, or CF₄. For example, the thermal etching is performed using a mixed gas of chlorine gas and oxygen gas as a reactive gas, at a heat treatment temperature of, for example, not less than 700° C. and not more than 1000° C.

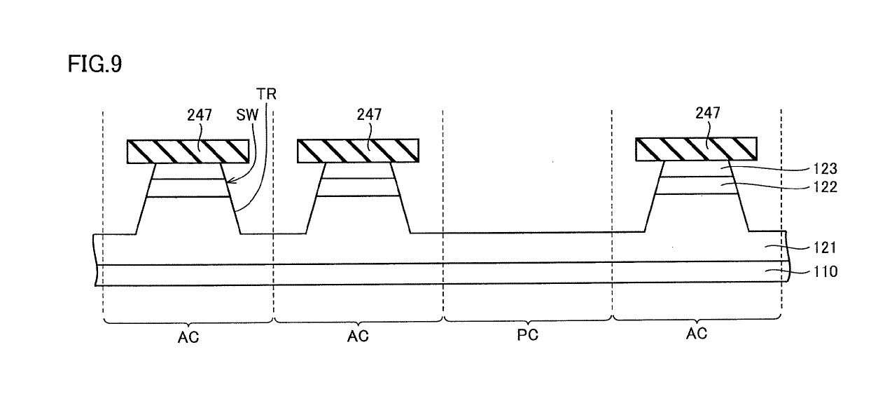

As a result of the thermal etching, trench TR is formed as shown in FIG. 9. On this occasion, as the side wall of trench TR, surface SW is formed which has portions respectively formed of n⁻ layer 121, p type body layer 122, and n region 123. In surface SW, the special plane is spontaneously formed.

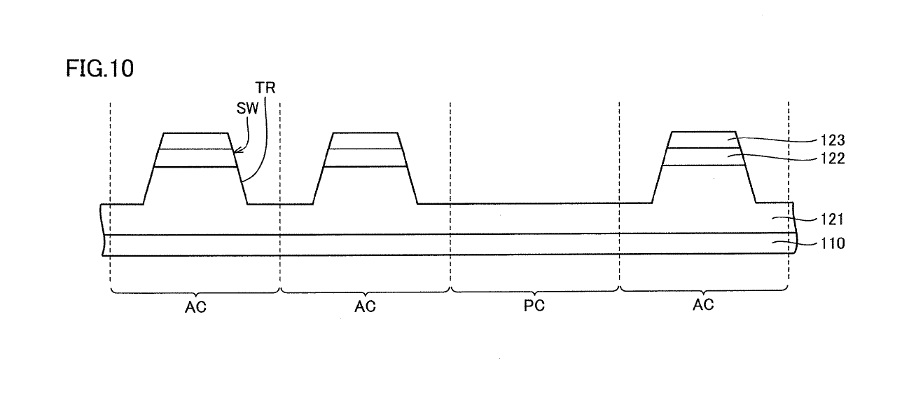

It should be noted that the reactive gas may contain a carrier gas in addition to the chlorine gas and the oxygen gas. An exemplary, usable carrier gas is nitrogen (N₂) gas, argon gas, helium gas, or the like. When the heat treatment temperature is set at not less than 700° C. and not more than 1000° C. as described above, a rate of etching SiC is approximately, for example, 70 μm/hour. In addition, in this case, each mask layer 247, which is formed of silicon oxide and therefore has a very large selection ratio relative to SiC, is not substantially etched during the etching of SiC. Next, mask layer 247 is removed by means of an appropriate method such as etching (FIG. 10).

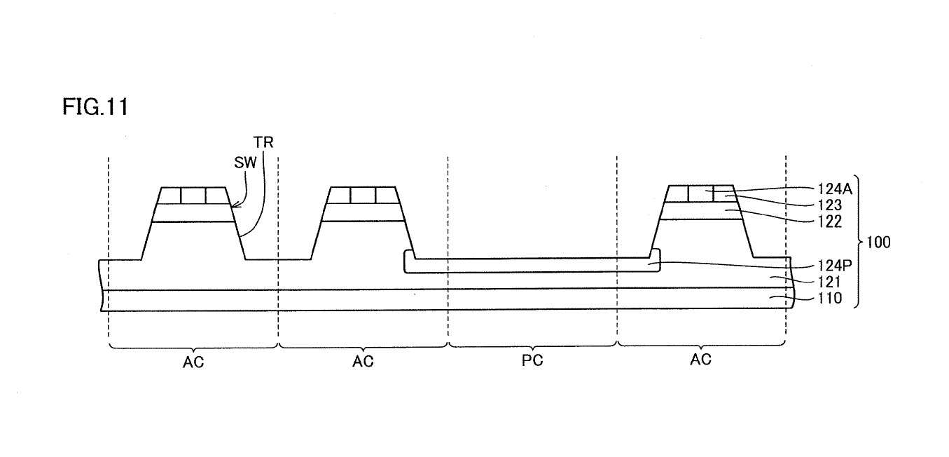

As shown in FIG. 11, by means of ion implantation, contact region 124A is formed in a portion of each of n regions 123. Further, in invalid cell PC, relaxing region 124P is formed in n⁻ layer 121. Next, activation annealing is performed to activate the impurities implanted by the ion implantation.

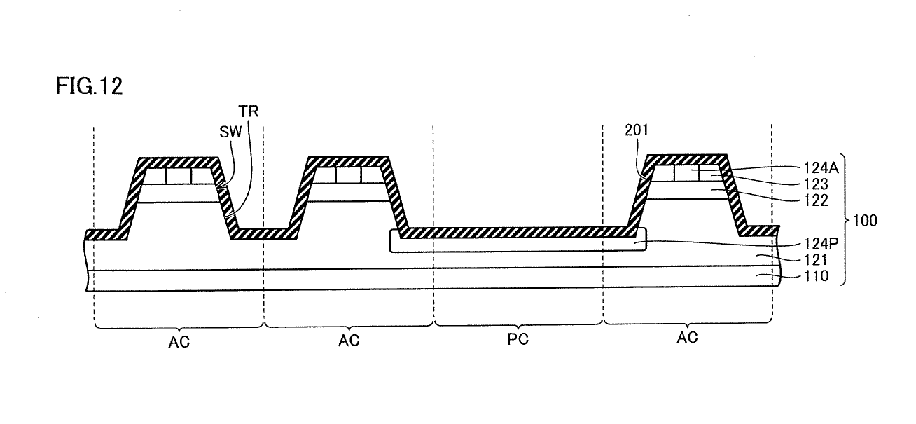

As shown in FIG. 12, gate insulating film 201 is formed on a surface including surface SW, which is the side wall of trench TR, and the bottom surface thereof. Gate insulating film 201 is obtained by, for example, thermally oxidizing the epitaxial layer made of silicon carbide.

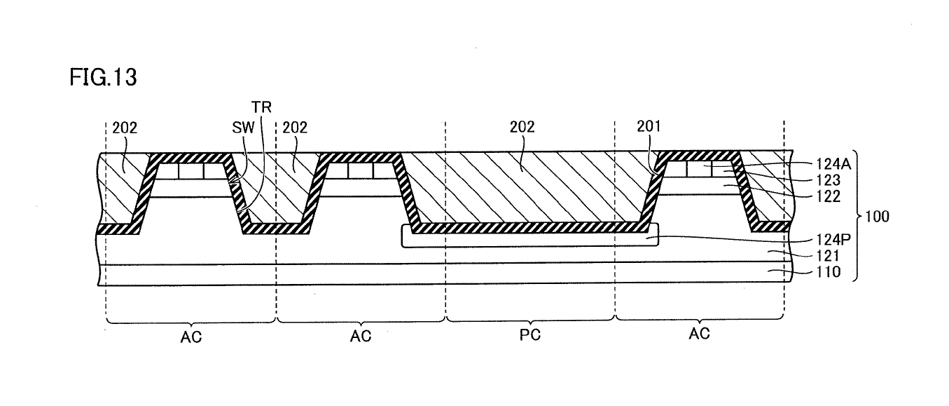

As shown in FIG. 13, gate electrode 202 is formed to fill the region in trench TR in valid cells AC as well as the region in invalid cell PC, with gate insulating film 201 being interposed therebetween. A method for forming gate electrode 202 can be performed by, for example, forming a film of conductor and performing CMP (Chemical Mechanical Polishing).

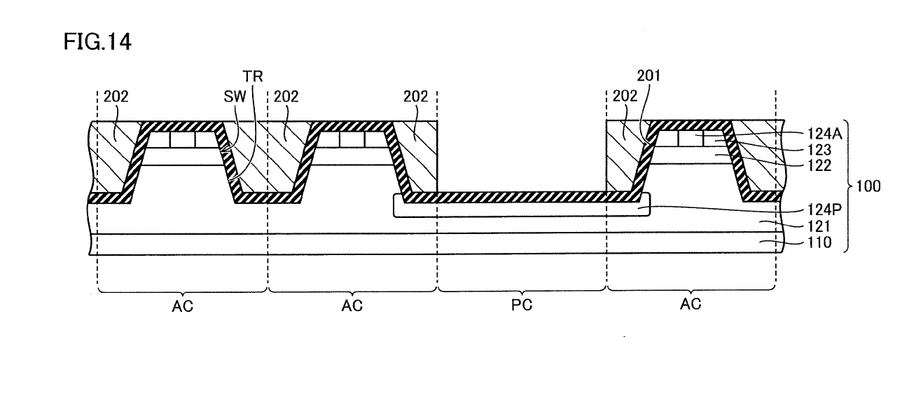

As shown in FIG. 14, in invalid cell PC, gate electrode 202 is removed by means of etching.

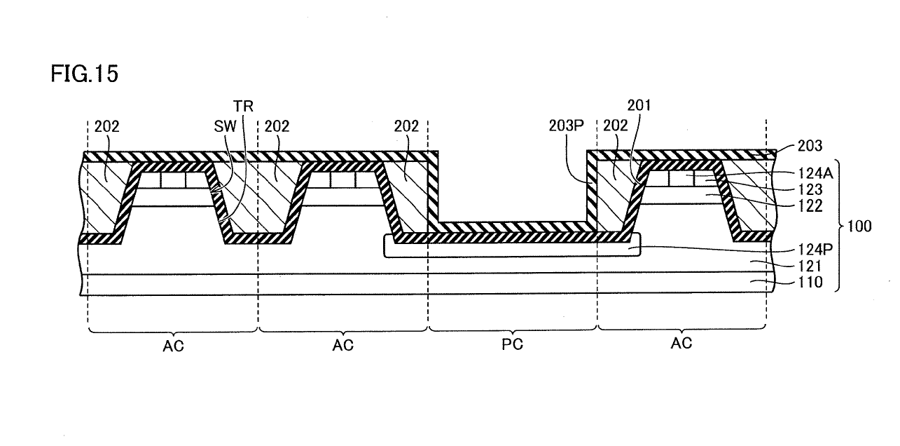

As shown in FIG. 15, interlayer insulating film 203 is formed to cover the exposed surfaces of gate electrodes 202.

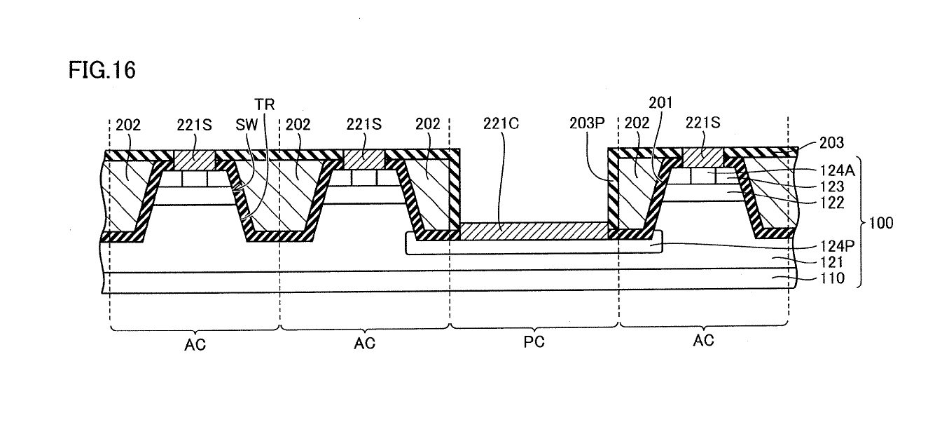

Referring to FIG. 16, etching is performed to form openings in interlayer insulating film 203 and gate insulating film 201. Through the openings, n regions 123 and contact regions 124A in the upper surfaces of the mesa structures are exposed, and relaxing region 124P is exposed in invalid cell PC. Next, in the upper surface of each mesa structure, source electrode 221 S is formed in contact with n regions 123 and contact region 124A. Relaxing electrode 221 C is formed in contact with relaxing region 124P.

Referring to FIG. 2 again, source wiring member 222, drain electrode 211, and protecting electrode 212 are formed. In this way, MOSFET 51H is obtained.

According to the present embodiment, as shown in FIG. 1, at least one valid cell AC is disposed between invalid cells PC adjacent to each other. Accordingly, significant current confinement, which would have taken place when invalid cells PC are disposed directly adjacent to each other, can be avoided. Moreover, in the case where invalid cells PC are periodically arranged in unit cells UC, electric field relaxation provided by invalid cells PC can affect valid cells AC more uniformly. Accordingly, breakdown voltage can be more improved.

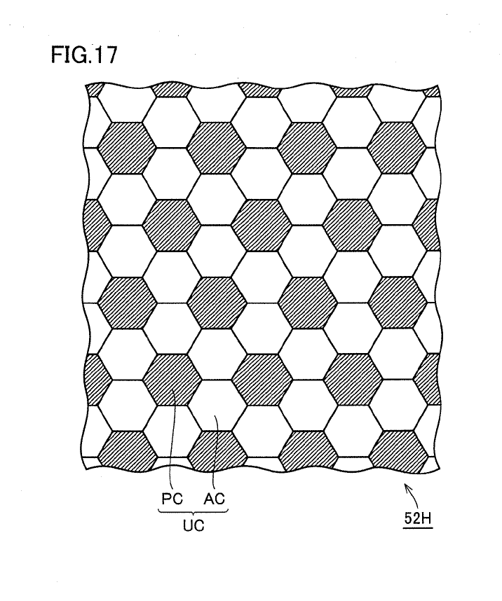

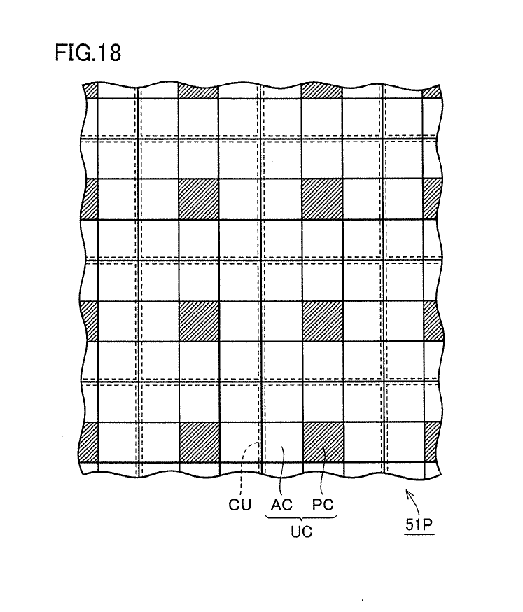

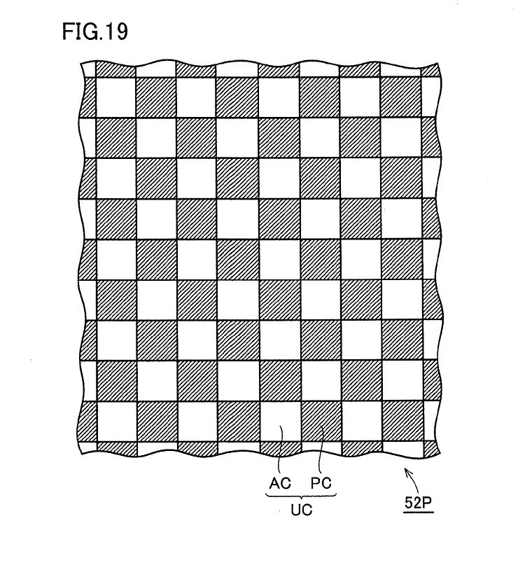

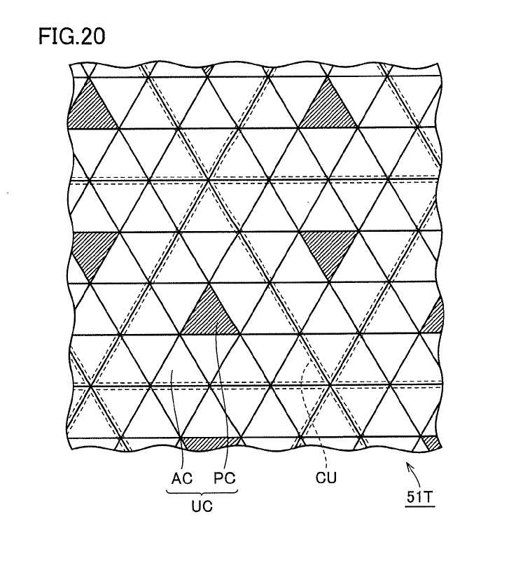

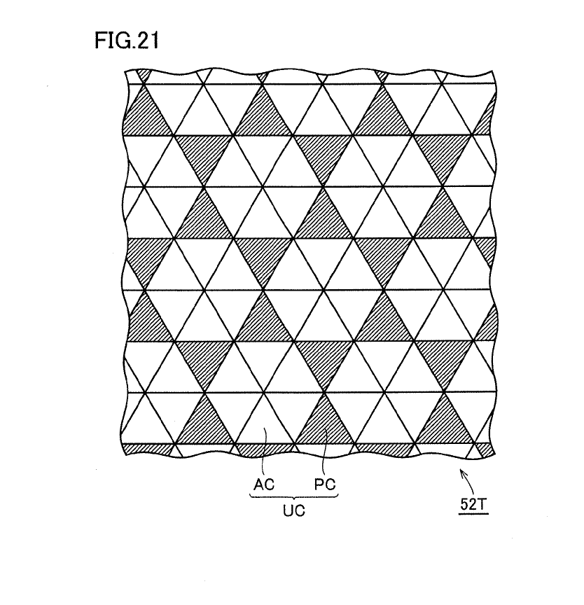

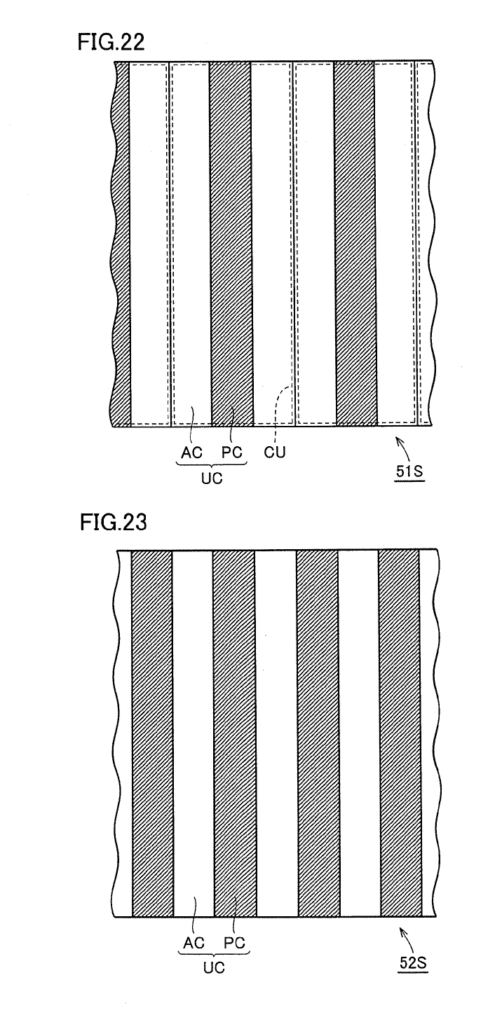

It should be noted that instead of MOSFET 51H having the planar layout shown in FIG. 1, any of MOSFETs 52H, 51P, 52P, 51T, 52T, 51S, and 52S respectively having planar layouts shown in FIG. 17 to FIG. 23 may be employed. In MOSFET 52H (FIG. 17), only one valid cell AC is disposed between adjacent invalid cells PC. In each of MOSFETs 51P and 52P (FIG. 18 and FIG. 19), each unit cell UC has a shape of rectangle (inclusive of square), and preferably has a shape of square. In each of MOSFETs 51T and 52T (FIG. 20 and FIG. 21), each unit cell UC has a shape of triangle, and preferably has a shape of regular triangle. It should be noted that in the case where unit cell UC has a shape of triangle, the expression “adjacent” is intended to mean that they are adjacent to each other with the sides of the triangles meeting each other. In each of MOSFETs 51S and 52S, each unit cell UC has a shape of stripe.

Further, in the present embodiment, as shown in FIG. 2, relaxing region 124P has the same potential as that of source wiring member 222, but may have floating potential.

### Second Embodiment

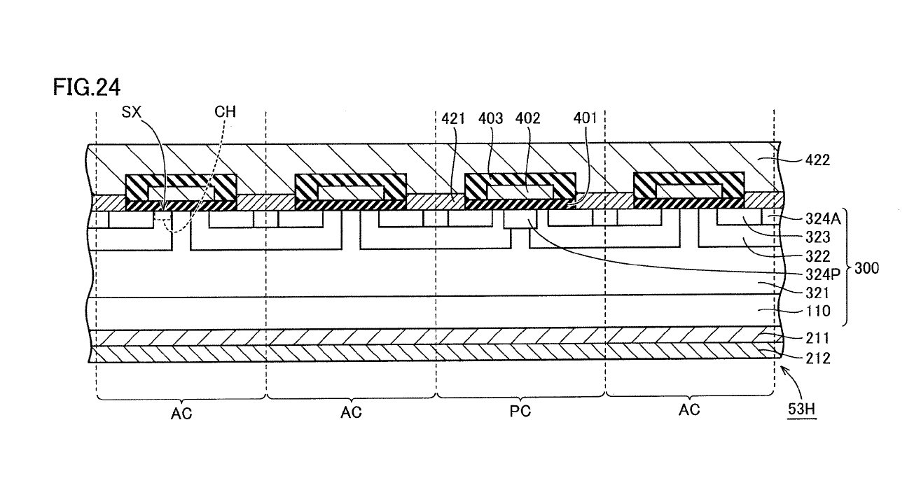

A MOSFET 53H (silicon carbide semiconductor device) of the present embodiment has a planar layout similar to the planar layout of MOSFET 51H (FIG. 1) in the first embodiment. Further, MOSFET 53H is a vertical, planar type MOSFET as shown in FIG. 24. MOSFET 53H includes an epitaxial substrate 300, gate insulating films 401, gate electrodes 402, interlayer insulating films 403, source electrodes 421, a drain electrode 211, a source wiring member 422, and a protecting electrode 212. Epitaxial substrate 300 is made of silicon carbide. Preferably, epitaxial substrate 300 has a hexagonal polytype of 4H. Preferably, epitaxial substrate 300 has a surface SX having a special plane.

Specifically, epitaxial substrate 300 has a single-crystal substrate 110 and an epitaxial layer provided on single-crystal substrate 110 and having surface SX. The epitaxial layer is made of silicon carbide, and includes an n⁻ layer 321 (breakdown voltage holding layer), p type body layers 322, n regions 323, contact regions 324A, and a relaxing region 324P. Single-crystal substrate 110, n⁻ layer 321, and n regions 323 have n type conductivity (first conductivity type), whereas p type body layers 322, contact regions 324A, and relaxing region 324P have p type conductivity (second conductivity type).

N⁻ layer 321 is provided on the upper surface of single-crystal substrate 110. N⁻ layer 321 has an impurity concentration lower than that of single-crystal substrate 110. Each of p type body layers 322 is formed in n⁻ layer 321 in the form of a well, and provides a channel surface CH on surface SX. In other words, surface SX has channel surface CH on p type body layer 322. Each of n regions 323 is formed on p type body layer 322 in a form of well so as to be separated from n⁻ layer 321 by p type body layers 322. Each of contact regions 324A is formed on a portion of p type body layer 322 so as to be connected to p type body layer 322.

On channel surface CH, gate insulating film 401 is provided. Relaxing region 324P covers n⁻ layer 321 on surface SX in a location corresponding to invalid cell PC among valid cells AC and invalid cell PC. Accordingly, in invalid cell PC, the p type region blocks the location between channel surface CH and n⁻ layer 321. This gate insulating film 401 extends on relaxing region 324P and the upper surface of n region 323.

Gate electrode 402 is provided on gate insulating film 401. Interlayer insulating film 403 covers gate electrode 402. Each of gate insulating film 401 and interlayer insulating film 403 has an opening in which each of n⁻ layer 323 and contact region 324A is exposed on surface SX. In this opening, source electrode 421 is in contact with n⁻ layer 323 and contact region 324A.

Source wiring member 422 is in contact with source electrode 421, and extends on the upper surface of interlayer insulating film 403.

Drain electrode 211 is an ohmic electrode provided on the backside surface of single-crystal substrate 110 opposite to its main surface on which n⁻ layer 321 is provided. Protecting electrode 212 is provided on drain electrode 211.

The following describes a method for manufacturing MOSFET 53H.

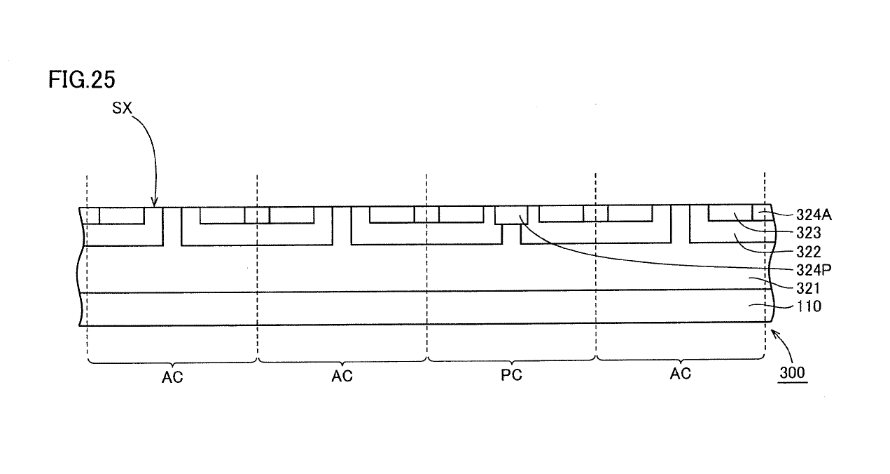

Referring to FIG. 25, single-crystal substrate 110 is prepared which is made of silicon carbide having a hexagonal single-crystal structure of polytype 4H. Next, on the upper surface of single-crystal substrate 110, the epitaxial layer made of silicon carbide is formed.

Next, the surface of the epitaxial layer is thermally etched. This etching can be performed by, for example, heating epitaxial substrate 300 in an atmosphere containing at least one or more types of halogen atom. The at least one or more types of halogen atom include at least one of chlorine (CO atom and fluorine (F) atom. This atmosphere is, for example, Cl₂, BCL₃, SF₆, or CF₄. With this thermal etching, surface SX having a special plane is spontaneously formed on the epitaxial layer.

Next, p type body layer 322, n region 323, contact region 324A, and relaxing region 324P are formed by means of ion implantation. Next, activation annealing treatment is performed to activate the implanted impurities. For example, heating is performed for 30 minutes at a temperature of approximately 1700° C. in an atmosphere of argon (Ar) gas.

It should be noted that the above-described thermal etching may be performed after the activation annealing. In this case, atomic arrangement in surface SX can be prevented from being disarranged by the activation annealing.

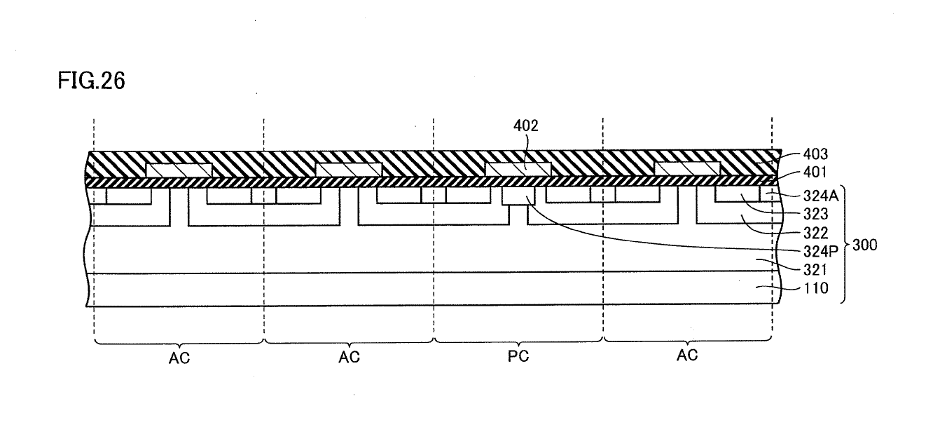

Referring to FIG. 26, gate insulating film 401 is formed on surface SX. Gate insulating film 401 is formed by means of, for example, dry oxidation (thermal oxidation). The dry oxidation is performed by performing heating for approximately 30 minutes at a temperature of approximately 1200° C. in air or oxygen, for example. Next, nitrogen annealing is performed. Accordingly, the nitrogen concentration is adjusted to have a maximum value of 1×10²¹/cm³ or greater in a region within 10 nm from an interface between epitaxial substrate 300 and gate insulating film 401. For example, in an atmosphere of gas containing nitrogen, such as nitrogen monoxide (NO) gas, heating is performed at a temperature of approximately 1100° C. for approximately 120 minutes. After this nitrogen annealing treatment, inert gas annealing treatment may be performed additionally. For example, in argon gas atmosphere, heating is performed at a temperature of approximately 1100° C. for approximately 60 minutes. Accordingly, high channel mobility can be attained with good reproducibility.

Next, gate electrode 402 is formed on gate insulating film 401. Next, interlayer insulating film 403 is formed to cover gate electrode 402 on gate insulating film 401.

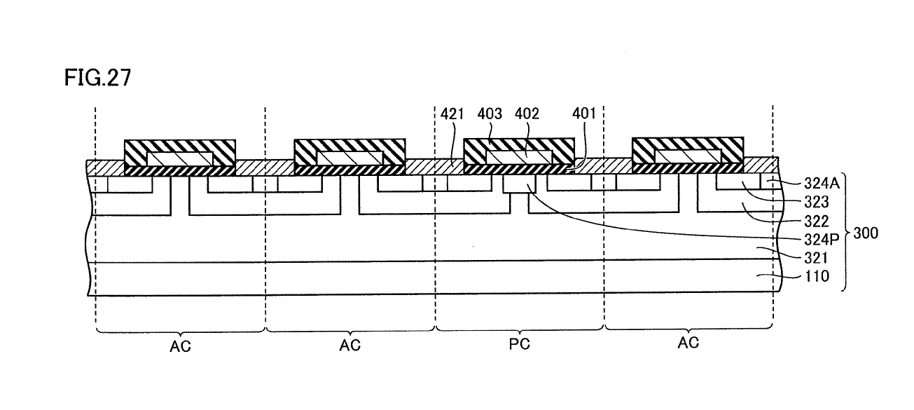

Referring to FIG. 27, gate insulating film 401 and interlayer insulating film 403 are then patterned, thereby providing openings in each of which n region 323 and contact region 324A are exposed. This patterning can be performed by means of, for example, photolithography and etching. Next, in each of the openings, source electrode 421 is formed in contact with each of n region 323 and contact region 324A.

Referring to FIG. 24 again, source wiring member 422, drain electrode 211, and protecting electrode 212 are formed. In this way, MOSFET 53H is obtained.

It should be noted that configurations other than the above are substantially the same as those of the first embodiment. Hence, the same or corresponding elements are given the same reference characters and are not described repeatedly.

### Third Embodiment

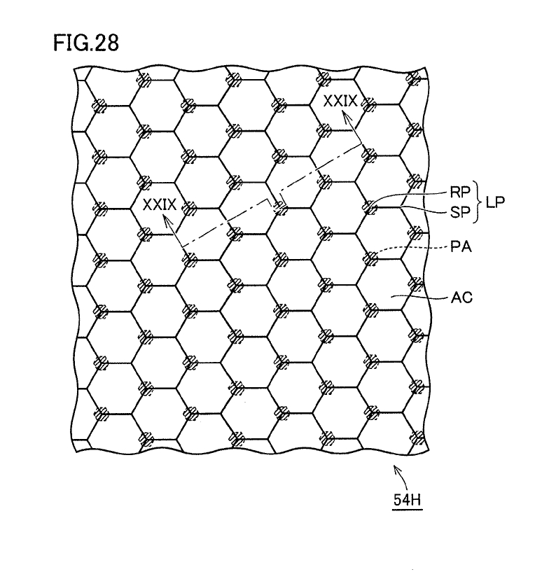

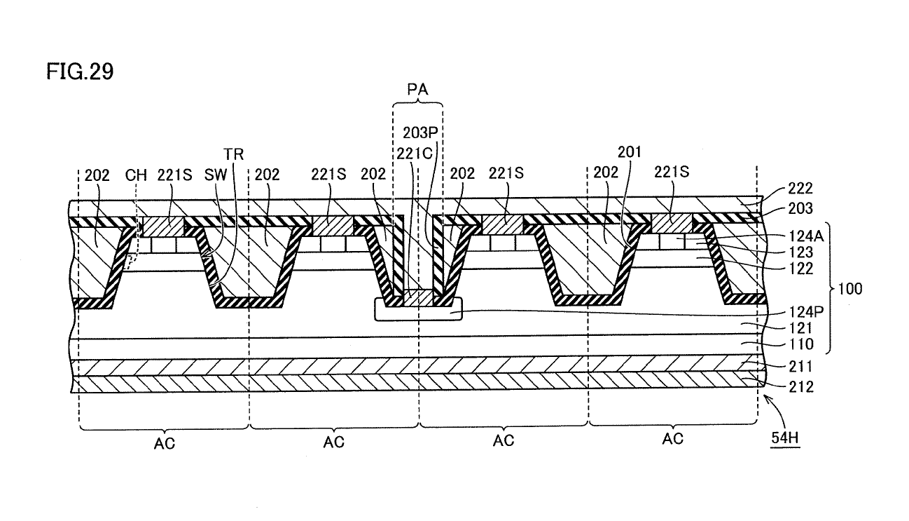

As shown in FIG. 28, a MOSFET 54H of the present embodiment has a planar layout configured by periodically arranging unit cells, each of which has a shape similar to that of unit cell UC (FIG. 1) of the first embodiment. MOSFET 54H has valid cells AC and invalid regions PA. Valid cells AC are included in the unit cells. With the sides of adjacent unit cells being connected with each other, the planar layout has a shape of lattice as shown in FIG. 28. The location in which such adjacent sides are connected to each other is called “lattice point”. Valid cells AC are periodically arranged to provide lattice points LP. Each of valid cells AC has a switchable channel surface CH (FIG. 29).

Lattice points LP include normal lattice points SP and relaxation lattice points RP. Between adjacent relaxation lattice points RP along the lattice, at least one normal lattice point SP (one in FIG. 28) is disposed. Invalid region PA is to relax electric field in valid cell AC. Invalid region PA is disposed for each of relaxation lattice points RP. As shown in FIG. 29, in invalid region PA, a configuration substantially the same as invalid cell PC of the first embodiment is provided.

Preferably, relaxation lattice points RP are periodically disposed in lattice points LP. In the configuration of FIG. 28, they are arranged such that three-fold symmetry of the planar layout is maintained.

According to the present embodiment, at least one normal lattice point SP is disposed between relaxation lattice points RP adjacent to each other. Accordingly, significant current confinement, which would have taken place when relaxation lattice points RP are disposed directly adjacent to each other, can be avoided.

Moreover, in the case where relaxation lattice points RP are periodically arranged in lattice points LP, electric field relaxation provided by relaxation lattice points RP can affect valid cells AC more uniformly. Accordingly, breakdown voltage can be more improved.

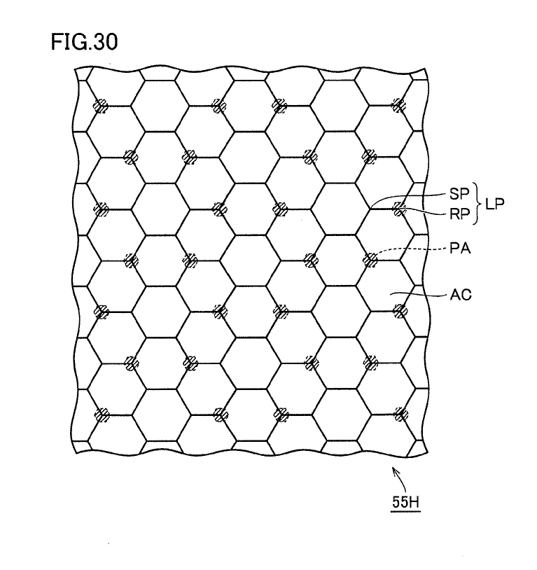

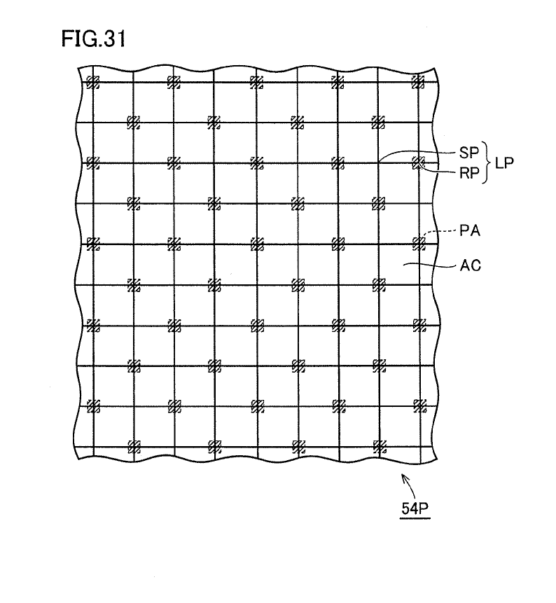

It should be noted that configurations other than the above are substantially the same as those of the first embodiment. Hence, the same or corresponding elements are given the same reference characters and are not described repeatedly. It should be also noted that instead of MOSFET 54H having the planar layout shown in FIG. 28, any of MOSFETs 55H, 54P, and 54T respectively having planar layouts shown in FIG. 30 to FIG. 32 may be employed. In MOSFET 54H (FIG. 30), two normal lattice points SP are disposed between adjacent relaxation lattice points RP. In MOSFET 54P (FIG. 31), each unit cell has a shape of rectangle (inclusive of square), and preferably has a shape of square. In MOSFET 54T (FIG. 32), each unit cell has a shape of triangle, and preferably has a shape of regular triangle.

### Fourth Embodiment

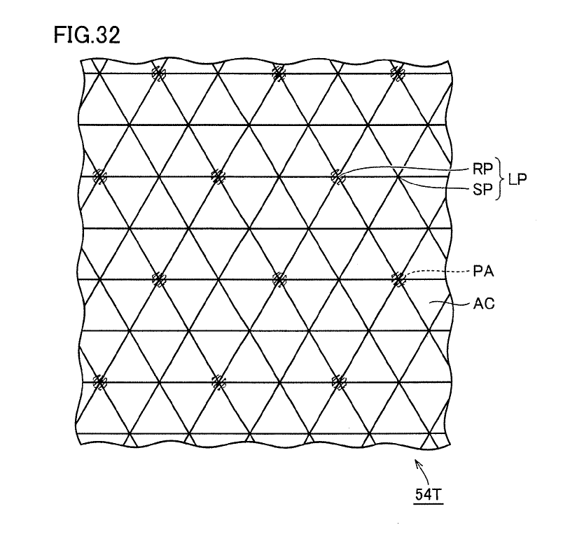

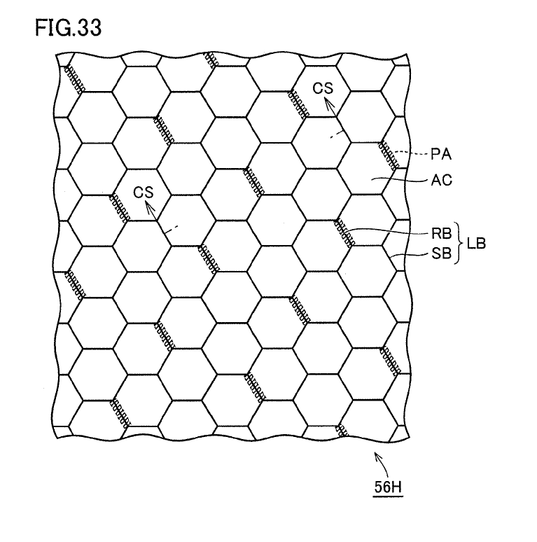

As shown in FIG. 33, a MOSFET 56H of the present embodiment has a planar layout configured by periodically arranging unit cells, each of which has a shape similar to that of unit cell UC (FIG. 1) of the first embodiment. MOSFET 56H has valid cells AC and invalid regions PA. Valid cells AC are included in the unit cells, and are periodically arranged. Each of valid cells AC has an outer edge surrounded by sides. Valid cells AC are in contact with each other with their sides serving as boundaries LB.

Boundaries LB have normal boundaries SB and relaxation boundaries RB. Between adjacent relaxation boundaries RB along the lattice, at least one normal boundary SB (three in FIG. 33) is disposed. Invalid region PA is to relax electric field in valid cell AC. Invalid region PA is disposed for each of relaxation boundaries RB. Preferably, relaxation boundaries RB are periodically disposed in boundaries LB.

According to the present embodiment, at least one normal boundary SB is disposed between adjacent relaxation boundaries RB. Accordingly, significant current confinement, which would have taken place when relaxation boundaries RB are disposed directly adjacent to each other, can be avoided.

Moreover, in the case where relaxation boundaries RB are periodically arranged in boundaries LB, electric field relaxation provided by relaxation boundaries RB can affect valid cells AC more uniformly. Accordingly, breakdown voltage can be more improved.

It should be noted that configurations other than the above are substantially the same as those of the third embodiment. Hence, the same or corresponding elements are given the same reference characters and are not described repeatedly. For example, the configuration in a cross section along a line CS-CS in FIG. 33 is similar to the configuration shown in FIG. 29 in the third embodiment.

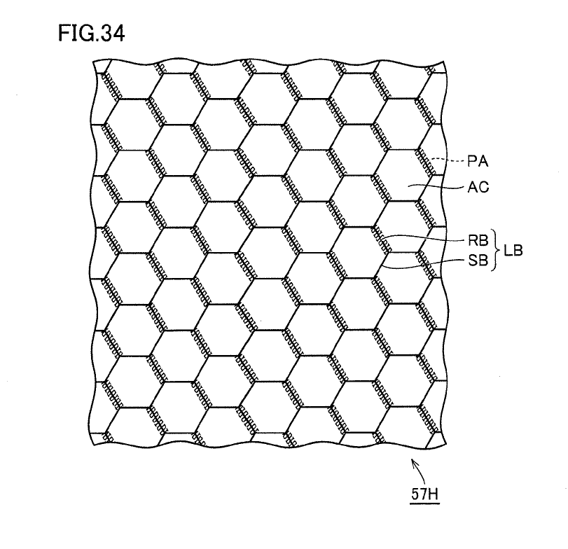

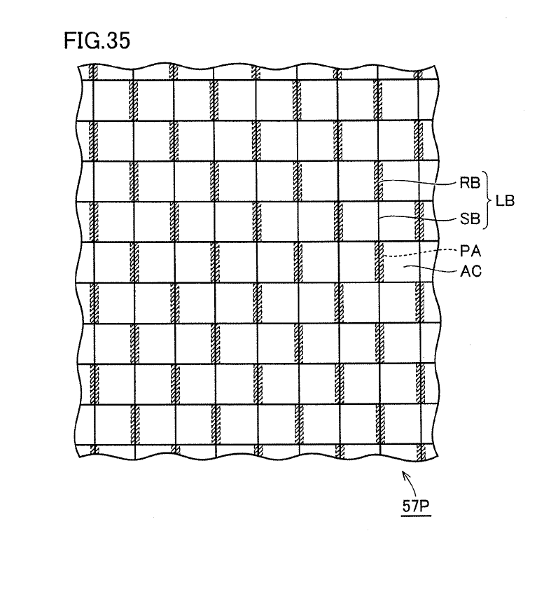

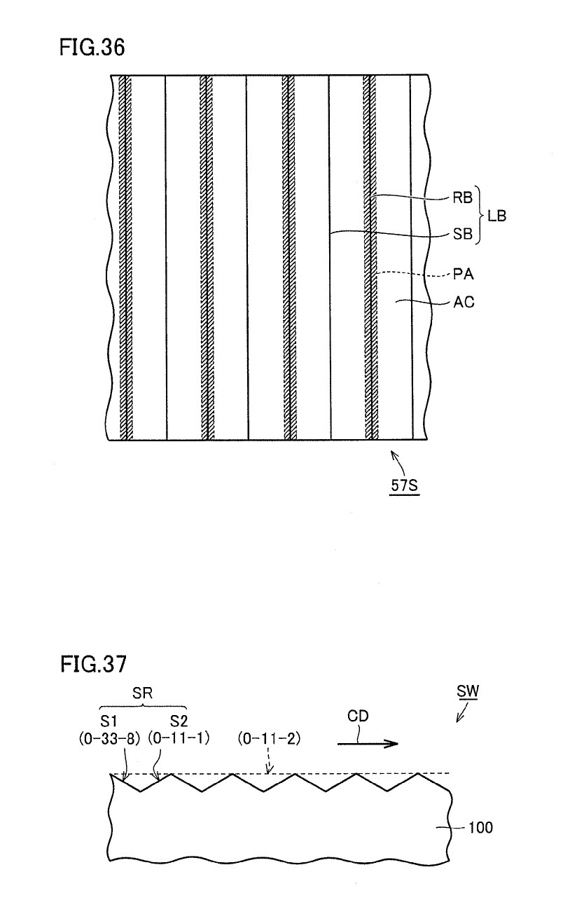

It should be also noted that instead of MOSFET 56H having the planar layout shown in FIG. 33, any of MOSFETs 57H, 57P, and 57S respectively having planar layouts shown in FIG. 34 to FIG. 36 may be employed. In MOSFET 57H (FIG. 34), one normal boundary SB is disposed between adjacent relaxation boundaries RB. In MOSFET 57P (FIG. 35), each unit cell has a shape of rectangle (inclusive of square), and preferably has a shape of square. In MOSFET 57S (FIG. 36), each unit cell has a shape of stripe.

By replacing n type and p type with each other in the MOSFET having the n channel in each of the above-described embodiments, the MOSFET may have a p channel. However, in order to obtain a higher channel mobility, the n channel is more preferable. Further, the silicon carbide semiconductor device may be a MISFET (Metal Insulator Semiconductor Field Effect Transistor) other than the MOSFET.

Moreover, the silicon carbide semiconductor device is not limited to the MISFET as long as it has a channel surface. For example, the semiconductor device may be an IGBT (Insulated Gate Bipolar Transistor).

(Surface Having Special Plane)

Surface SW (FIG. 2) including channel surface CH has the special plane, so that channel surface CH also has the special plane. As shown in FIG. 37, surface SW having the special plane has a plane Si (first plane). Plane 51 has a plane orientation of {0-33-8}, and preferably has a plane orientation of (0-33-8). Preferably, surface SW microscopically includes plane S1. Preferably, surface SW further microscopically includes a plane S2 (second plane). Plane S2 has a plane orientation of {0-11-1}, and preferably has a plane orientation of (0-11-1). Here, the term “microscopically” refers to “minutely to such an extent that at least the size about twice as large as an interatomic spacing is considered”. As a method for observing such a microscopic structure, for example, a TEM (Transmission Electron Microscope) can be used.

Preferably, surface SW has a combined plane SR. Combined plane SR is constituted of periodically repeated planes S1 and S2. Such a periodic structure can be observed by, for example, TEM or AFM (Atomic Force Microscopy). Combined plane SR has a plane orientation of {0-11-2}, and preferably has a plane orientation of (0-11-2). In this case, combined plane SR has an off angle of 62° relative to the {000-1} plane, macroscopically. Here, the term “macroscopically” refers to “disregarding a fine structure having a size of approximately interatomic spacing”. For the measurement of such a macroscopic off angle, a method employing general X-ray diffraction can be used, for example. Preferably, in channel surface CH, carriers flow in a channel direction CD, in which the above-described periodic repetition is done.

The following describes a detailed structure of combined plane SR.

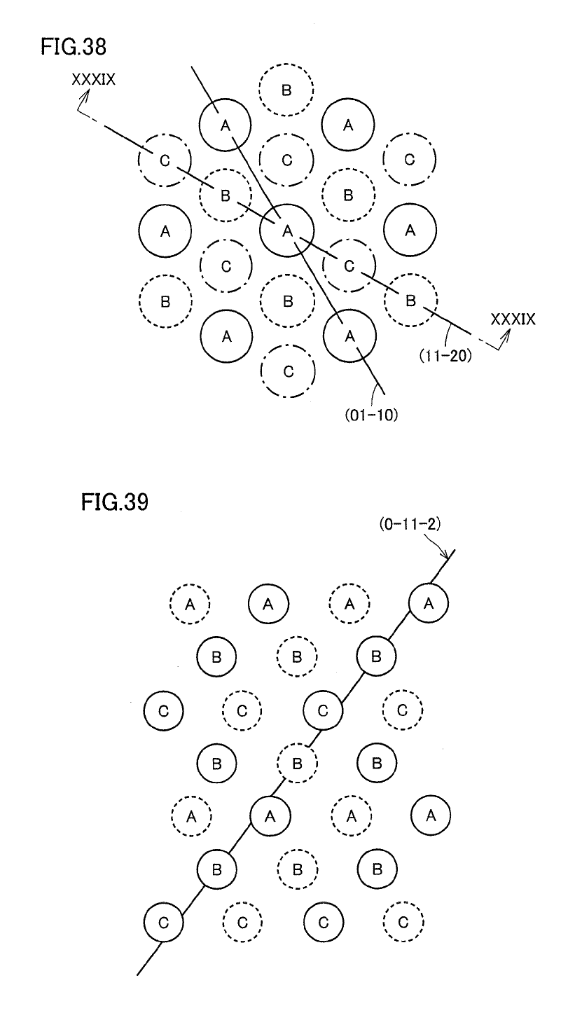

Generally, regarding Si atoms (or C atoms), when viewing a silicon carbide single-crystal of polytype 4H from the (000-1) plane, atoms in a layer A (solid line in the figure), atoms in a layer B (broken line in the figure) disposed therebelow, and atoms in a layer C (chain line in the figure) disposed therebelow, and atoms in a layer B (not shown in the figure) disposed therebelow are repeatedly provided as shown in FIG. 38. In other words, with four layers ABCB being regarded as one period, a periodic stacking structure such as ABCBABCBABCB . . . is provided.

As shown in FIG. 39, in the (11-20) plane (cross section taken along a line XXXIX-XXXIX of FIG. 38), atoms in each of four layers ABCB constituting the above-described one period are not aligned completely along the (0-11-2) plane. In FIG. 39, the (0-11-2) plane is illustrated to pass through the locations of the atoms in layers B. In this case, each of atoms in layers A and B is deviated from the (0-11-2) plane. Hence, even when the macroscopic plane orientation of the surface of the silicon carbide single-crystal, i.e., the plane orientation thereof with its atomic level structure being disregarded is limited to (0-11-2), this surface can have various structures microscopically.

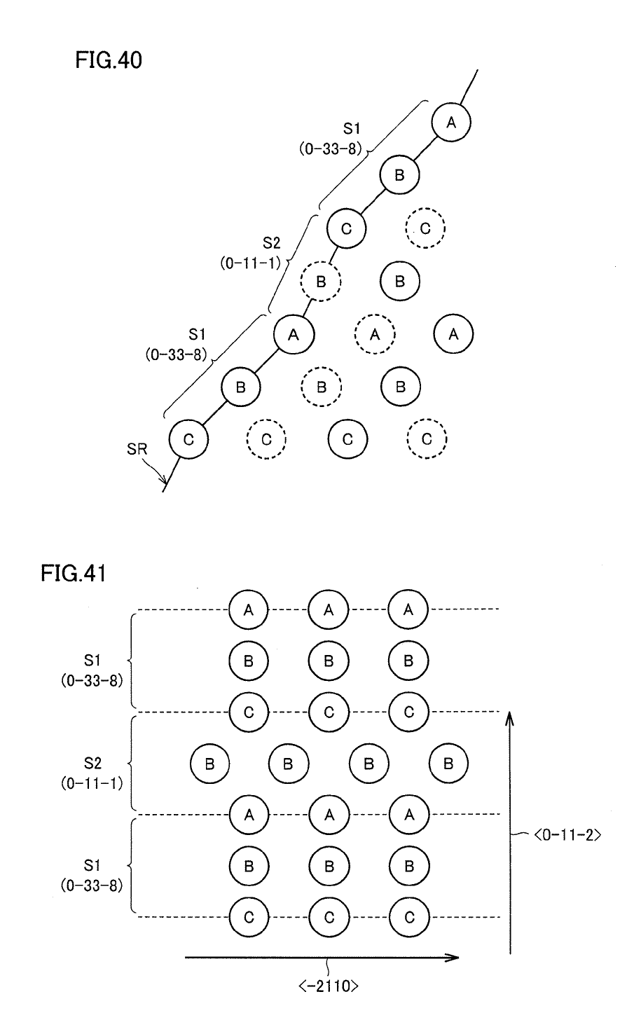

As shown in FIG. 40, combined surface SR is constructed by alternately providing planes S1 having a plane orientation of (0-33-8) and planes S2 connected to planes S1 and having a plane orientation different from that of each of planes S1. Each of planes S1 and S2 has a length twice as large as the interatomic spacing of the S1 atoms (or C atoms). It should be noted that a plane with plane Si and plane S2 being averaged corresponds to the (0-11-2) plane (FIG. 39).

As shown in FIG. 41, when viewing combined surface SR from the (01-10) plane, the single-crystal structure has a portion periodically including a structure (plane S1 portion) equivalent to a cubic structure. Specifically, combined surface SR is constructed by alternately providing planes Si having a plane orientation of (001) in the above-described structure equivalent to the cubic structure and planes S2 connected to planes S1 and having a plane orientation different from that of each of planes S1. Also in polytype other than 4H, the surface can be thus constituted of the planes (planes S1 in FIG. 41) having a plane orientation of (001) in the structure equivalent to the cubic structure and the planes (planes S2 in FIG. 41) connected to the foregoing planes and having a plane orientation different from that of each of the foregoing planes. The polytype may be, for example, 6H or 15R.

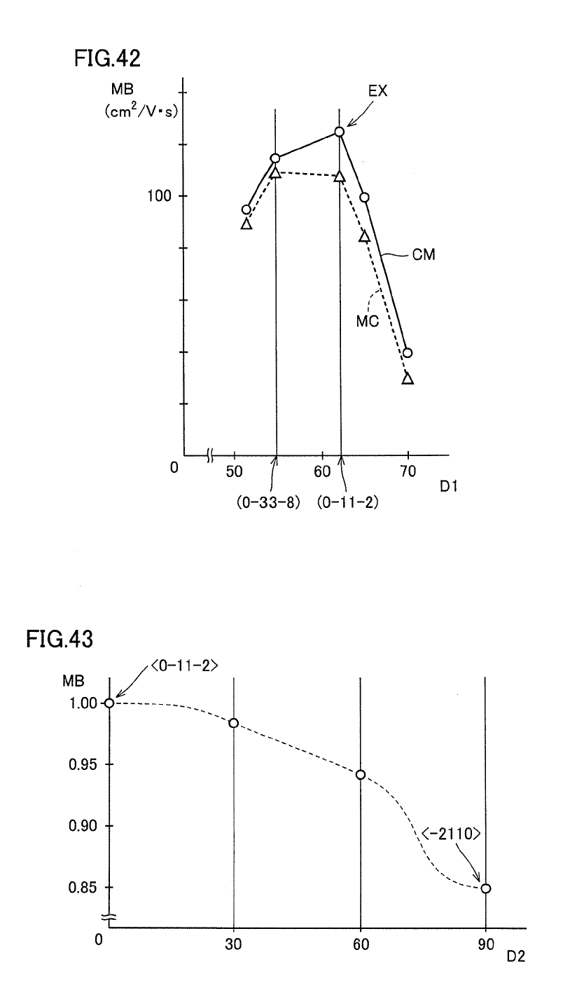

Referring to FIG. 42, the following describes a relation between the crystal plane of surface SW and mobility MB in channel surface CH. In the graph of FIG. 42, the horizontal axis represents an angle D1 formed by the (000-1) plane and the macroscopic plane orientation of surface SW having channel surface CH, whereas the vertical axis represents mobility MB. A group of plots CM correspond to a case where surface SW is finished to have the special plane through thermal etching, whereas a group of plots MC correspond to a case where surface SW is not thermally etched as such.

In group of plots MC, mobility MB is at maximum when the surface of channel surface CH has a macroscopic plane orientation of (0-33-8). This is presumably due to the following reason. That is, in the case where the thermal etching is not performed, i.e., in the case where the microscopic structure of the channel surface is not particularly controlled, the macroscopic plane orientation thereof corresponds to (0-33-8), with the result that a ratio of the microscopic plane orientation of (0-33-8), i.e., the plane orientation of (0-33-8) in consideration of that in atomic level becomes statistically high.

On the other hand, mobility MB in group of plots CM is at maximum when the macroscopic plane orientation of the surface of channel surface CH is (0-11-2) (arrow EX). This is presumably due to the following reason. That is, as shown in FIG. 40 and FIG. 41, the multiplicity of planes S1 each having a plane orientation of (0-33-8) are densely and regularly arranged with planes S2 interposed therebetween, whereby a ratio of the microscopic plane orientation of (0-33-8) becomes high in the surface of channel surface CH.

It should be noted that mobility MB has orientation dependency on combined plane SR. In a graph shown in FIG. 43, the horizontal axis represents an angle D2 between the channel direction and the <0-11-2>direction, whereas the vertical axis represents mobility MB (in any unit) in channel surface CH. A broken line is supplementarily provided therein for viewability of the graph. From this graph, it has been found that in order to increase channel mobility MB, channel direction CD (FIG. 37) preferably has an angle D2 of not less than 0° and not more than 60°, more preferably, substantially 0°.

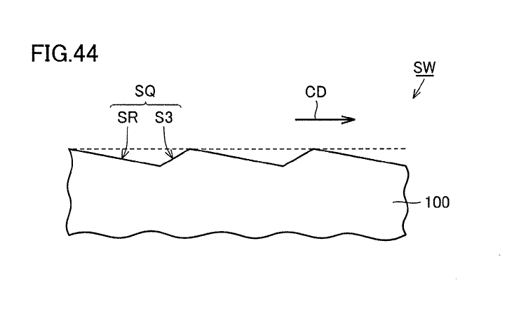

As shown in FIG. 44, surface SW may further include plane S3 (third plane) in addition to combined plane SR. In this case, the off angle of surface SW relative to the {000-1} plane is deviated from the ideal off angle of combined plane SR, i.e., 62°. Preferably, this deviation is small, preferably, in a range of ±10°. Examples of a surface included in such an angle range include a surface having a macroscopic plane orientation of the {0-33-8} plane. More preferably, the off angle of surface SW relative to the (000-1) plane is deviated from the ideal off angle of combined plane SR, i.e., 62°. Preferably, this deviation is small, preferably, in a range of ±10°. Examples of a surface included in such an angle range include a surface having a macroscopic plane orientation of the (0-33-8) plane. More specifically, surface SW may include a combined plane SQ constituted of periodically repeated plane S3 and combined plane SR. Such a periodic structure can be observed by, for example, TEM or AFM (Atomic Force Microscopy).

Although the above description has illustrated surface SW having the special plane in detail, the same applies to surface SX (FIG. 24) having the special plane. Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device having a planar layout configured by periodically arranging unit cells, comprising:
a plurality of valid cells, which are included in said plurality of unit cells and each of which has a switchable channel surface; and
a plurality of invalid cells, included in said plurality of unit cells, for relaxing electric field in said plurality of valid cells, at least one of said plurality of valid cells being disposed between adjacent ones of said plurality of invalid cells.

2. The silicon carbide semiconductor device according to claim 1, wherein said plurality of invalid cells are periodically arranged in said plurality of unit cells.

3. The silicon carbide semiconductor device according to claim 1, wherein each of said plurality of valid cells has a source electrode.

4. The silicon carbide semiconductor device according to claim 1, wherein the silicon carbide semiconductor device is of trench gate type.

5. The silicon carbide semiconductor device according to claim 1, comprising:
a substrate that is made of silicon carbide having a hexagonal crystal structure of polytype 4H and that is provided with a surface including a first plane having a plane orientation of {0-33-8}, said surface including said channel surface;
a gate insulating film provided on said surface of said substrate; and
a gate electrode provided on said gate insulating film.

6. The silicon carbide semiconductor device according to claim 5, wherein said surface microscopically includes said first plane, and said surface microscopically includes a second plane having a plane orientation of {0-11-1}.

7. The silicon carbide semiconductor device according to claim 6, wherein said first and second planes of said substrate form a combined plane having a plane orientation of {0-11-2}.

8. The silicon carbide semiconductor device according to claim 7, wherein said surface of said substrate macroscopically has an off angle of 62°±10° relative to a {000-1} plane.

9. A silicon carbide semiconductor device having a planar layout configured by periodically arranging unit cells, comprising:
a plurality of valid cells, which are included in said plurality of unit cells, which are periodically arranged to provide a plurality of lattice points, and each of which has a switchable channel surface, said plurality of lattice points including a plurality of normal lattice points and a plurality of relaxation lattice points, at least one of said plurality of normal lattice points being disposed between adjacent ones of said plurality of relaxation lattice points; and
an invalid region, disposed for each of said plurality of relaxation lattice points, for relaxing electric field in said plurality of valid cells.

10. The silicon carbide semiconductor device according to claim 9, wherein said plurality of relaxation lattice points are periodically disposed in said plurality of lattice points.

11. The silicon carbide semiconductor device according to claim 9, wherein the silicon carbide semiconductor device is of trench gate type.

12. The silicon carbide semiconductor device according to claim 9, comprising:
a substrate that is made of silicon carbide having a hexagonal crystal structure of polytype 4H and that is provided with a surface including a first plane having a plane orientation of {0-33-8}, said surface including said channel surface;
a gate insulating film provided on said surface of said substrate; and
a gate electrode provided on said gate insulating film.

13. The silicon carbide semiconductor device according to claim 12, wherein said surface microscopically includes said first plane, and said surface microscopically includes a second plane having a plane orientation of {0-11-1}.

14. The silicon carbide semiconductor device according to claim 13, wherein said first and second planes of said substrate form a combined plane having a plane orientation of {0-11-2}.

15. The silicon carbide semiconductor device according to claim 14, wherein said surface of said substrate macroscopically has an off angle of 62°±10° relative to a {000-1} plane.

16. A silicon carbide semiconductor device having a planar layout configured by periodically arranging unit cells, comprising:
a plurality of valid cells, which are included in said plurality of unit cells, which are periodically arranged, and each of which has a switchable channel surface, each of said plurality of valid cells having an outer edge surrounded by a plurality of sides, said plurality of valid cells being in contact with each other with said plurality of sides serving as a plurality of boundaries, said plurality of boundaries having a plurality of normal boundaries and a plurality of relaxation boundaries, at least one of said plurality of normal boundaries being disposed between adjacent ones of said plurality of relaxation boundaries; and
an invalid region, disposed for each of said plurality of relaxation boundaries, for relaxing electric field in said plurality of valid cells.

17. The silicon carbide semiconductor device according to claim 16, wherein said plurality of relaxation boundaries are periodically arranged in said plurality of boundaries.

18. The silicon carbide semiconductor device according to claim 16, wherein the silicon carbide semiconductor device is of trench gate type.

19. The silicon carbide semiconductor device according to claim 16, comprising:
a substrate that is made of silicon carbide having a hexagonal crystal structure of polytype 4H and that is provided with a surface including a first plane having a plane orientation of {0-33-8}, said surface including said channel surface;
a gate insulating film provided on said surface of said substrate; and
a gate electrode provided on said gate insulating film.

20. The silicon carbide semiconductor device according to claim 19, wherein said surface microscopically includes said first plane, and said surface microscopically includes a second plane having a plane orientation of {0-11-1}.

21. The silicon carbide semiconductor device according to claim 20, wherein said first and second planes of said substrate form a combined plane having a plane orientation of {0-11-2}.

22. The silicon carbide semiconductor device according to claim 21, wherein said surface of said substrate macroscopically has an off angle of 62°±10° relative to a {000-1} plane.
